(19) United States
(12) Patent Application Publication
(10) Pub. No.: US 2007/0178665 A1
(43) Pub. Date: Aug. 2, 2007

(54) Systems And Methods For Forming Integrated Circuit Components Having Precise Characteristics

(76) Inventor: Craig A. West, Austin, TX (US)

Correspondence Address: BAKER BOTTS L.L.P.;PATENT DEPARTMENT, 98 SAN JACINTO BLVD., SUITE 1500, AUSTIN, TX, 78701-4039, US

(21) Appl. No.: 11/626,979

(22) Filed: Jan. 25, 2007

Related U.S. Application Data
(63) Continuation of application No. PCT/US05/26230, filed on Jul. 25, 2005.
(60) Provisional application No. 60/591,511, filed on Jul. 27, 2004.

(51) Int. Cl. H01L 21/76

(52) U.S. Cl. 438/427

(57) ABSTRACT

A method of forming integrated circuit components is provided. A photomask is provided that includes a first mask feature having a mask feature geometry corresponding to a first type of integrated circuit (IC) component. A first lithography process is performed to transfer the first mask feature geometry to a semiconductor wafer to form a first IC component on the semiconductor wafer. At least one electrical characteristic of the first IC component on the semiconductor wafer is measured. The first mask feature geometry is physically modified based at least on the results of measuring the at least one electrical characteristic of the first IC component.

### TECHNICAL FIELD OF THE INVENTION

This invention relates in general to integrated circuit fabrication and, more particularly, to a system and method for forming integrated circuit components having precise characteristics.

### BACKGROUND OF THE INVENTION

Integrated circuit devices typically include various circuit components, such as various transistors, resistors and capacitors, for example. Such integrated circuit components may be produced by forming particular geometries in a semiconductor wafer (e.g., a silicon wafer) using various integrated circuit fabrication techniques, such as various deposition and lithography techniques. In some instances, two or more electrical components of an integrated circuit device are related to each other such that one or more characteristics of the electrical components must “match” in order for the integrated circuit device to operate properly. For example, it may be necessary for a particular pair of resistors in an integrated circuit device to provide an equal amount of resistance in order for the device to operate properly or as desired. As another example, it may be necessary for a particular pair of capacitors in an integrated circuit device to provide an equal amount of capacitance in order for the device to operate properly or as desired.

In order to provide such components having “matching” electrical characteristics, attempts have been made to form components having identical geometries in the semiconductor wafer. However, various factors often cause imperfections and inconsistencies in the geometries of integrated circuit components formed in a semiconductor wafer, such as imperfections in the geometries formed in a photomask used in the formation of the integrated circuit components, imperfections associated with the lithographic imaging of the integrated circuit components, imperfections associated with the lens used for the lithographic imaging process, and/or imperfections caused by the reflection of light during the lithographic imaging process, for example.

If it is determined that a pair of integrated circuit components that are required to match do not in fact match, the physical geometry of one or both of the pair of components on the semiconductor wafer may be modified. Using a conventional technique, for example, “tabs” may be laser ablated to one or both of the components until the relevant electrical characteristic(s) of the components are determined to match. Such manipulation of the components on the semiconductor wafer may add cycle time and manpower, which may reduce the efficiency and may thus increase the costs of fabricating integrated circuit devices.

### SUMMARY OF THE INVENTION

In accordance with teachings of the present invention, disadvantages and problems associated with forming integrated circuit components having precise electrical properties on a wafer have been substantially reduced or eliminated. Generally, a photomask may be tested and modified using a iterative process to form a desired photomask. For example, a photomask may be used in a lithography process to form a test component, one or more electrical characteristics of the test component may be tested, and if the results of the test are unsatisfactory, the photomask may be modified and the process repeated until the photomask produces a test component having desired electrical characteristics. The photomask may then be used to form components on any suitable number of wafers.

In one embodiment, a method of forming integrated circuit components is provided. A photomask may be provided that includes a first mask feature having a first mask feature geometry corresponding to a first type of integrated circuit (IC) component. A first lithography process may be performed to transfer the first mask feature geometry to a semiconductor wafer to form a first IC component on the semiconductor wafer. At least one electrical characteristic of the first IC component may be measured. The first mask feature geometry may be physically modified based at least on the results of measuring the at least one electrical characteristic of the first IC component.

In another embodiment, another method of forming integrated circuit components is provided. A photomask may be provided that includes a first mask feature having a first mask feature geometry corresponding to a first type of IC component and a second mask feature having a second mask feature geometry corresponding to a second type of IC component. A first lithography process may be performed to transfer the first mask feature geometry and the second mask feature geometry to a first semiconductor wafer region to form a first IC component and a second IC component in the first semiconductor wafer region. At least one electrical characteristic of each of the first and second IC components may be measured. The at least one measured electrical characteristic of the first IC component may be compared with the at least one measured electrical characteristic of the second IC component. Based on the comparison of the measured electrical characteristics, a determination may be made regarding whether to physically modify at least one of the first mask feature geometry and the second mask feature geometry.

In yet another embodiment, another method of forming integrated circuit components is provided. A first photomask and second photomask may be provided. The first photomask may include a first mask feature having a first mask feature geometry corresponding to a first type of IC component, and the second photomask may include one or more second mask features each having a second mask feature geometry corresponding to a second type of IC component. A first lithography process using the first photomask may be performed to transfer the first mask feature geometry to a first semiconductor wafer region to form a first IC component in the first semiconductor wafer region. A second lithography process using the second photomask may be performed to transfer the second mask feature geometry of each of the one or more second mask features to the first semiconductor wafer region to form one or more second IC components in the first semiconductor wafer region, each of the one or more second IC components being coupled to the first IC component. At least one electrical characteristic of the first IC component may be measured. Based at least on the results of measuring the at least one electrical characteristic of the first IC component, the second mask feature geometry of at least one of the second mask features may be physically modified.

One advantage is that systems and methods may be provided for forming critical-performance integrated circuit components. In some embodiments, a photomask may be tested and modified using a iterative process to form a desired photomask, which may then be used to produce integrated circuit components having satisfactory electrical characteristics on any suitable number of semiconductor wafers. Using such techniques, the amount of modification (such as trimming or laser ablation, for example) to the integrated circuit components formed on the semiconductor wafers may be reduced or eliminated as compared with previous techniques for producing critical-performance integrated circuit components, which may thereby reduce cycle time, increase throughput, and/or reduce costs.

All, some, or none of these technical advantages may be present in various embodiments of the present invention. Other technical advantages will be readily apparent to one skilled in the art from the following figures, descriptions, and claims.

### BRIEF DESCRIPTION OF THE DRAWINGS

A more complete and thorough understanding of the present embodiments and advantages thereof may be acquired by referring to the following description taken in conjunction with the accompanying drawings, in which like reference numbers indicate like features, and wherein:

FIG. 1 illustrates a cross-sectional view of an example photomask assembly according to certain embodiments of the present invention;

FIG. 2 is partial three-dimensional view illustrating a lithography process used to form critical-performance integrated circuit components according to an embodiment of the present invention;

FIGS. 3A-3C are top views of a component formed in the patterned layer of a photomask illustrating example methods for modifying the geometry of the component in accordance with certain embodiments of the present invention;

FIG. 4 illustrates a flow chart of an iterative method for forming critical-performance integrated circuit components in semiconductor wafers according to an embodiment of the present invention;

FIG. 5 is a three-dimensional view illustrating a portion of an integrated circuit formed in a semiconductor wafer in accordance with an embodiment of the present invention; and

FIG. 6 is a top view of a portion of a photomask having a patterned layer including a pair of mask features used to form a pair of interconnects for a resistor in accordance with an embodiment of the present invention.

### DETAILED DESCRIPTION OF THE INVENTION

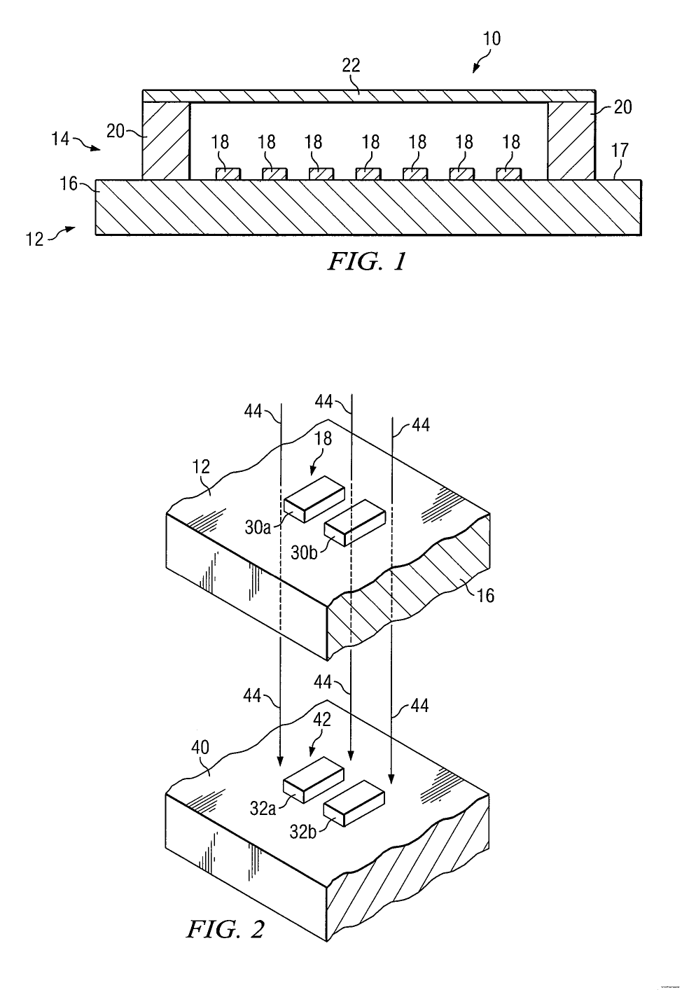

Preferred embodiments of the present invention and their advantages are best understood by reference to FIGS. 1 through 6, where like numbers are used to indicate like and corresponding parts.

FIG. 1 illustrates a cross-sectional view of an example photomask assembly 10 according to certain embodiments of the invention. Photomask assembly 10 may include a pellicle assembly 14 mounted on a photomask 12. A substrate 16 and a patterned layer 18 may form photomask 12, otherwise known as a mask or reticle, that may have a variety of sizes and shapes, including but not limited to round, rectangular, or square, for example. Photomask 12 may also be any variety of photomask types, including, but not limited to, a one-time master, a five-inch reticle, a six-inch reticle, a nine-inch reticle or any other appropriately sized reticle that may be used to project an image of a circuit pattern onto a semiconductor wafer. Photomask 12 may further be a binary mask, a phase shift mask (PSM) (e.g., an alternating aperture phase shift mask, also known as a Levenson type mask), an optical proximity correction (OPC) mask or any other type of mask suitable for use in a lithography system.

Photomask 12 may include patterned layer 18 formed on a top surface 17 of substrate 16 that, when exposed to electromagnetic energy in a lithography system, may project a pattern onto a surface of a semiconductor wafer (not expressly shown). In some embodiments, substrate 16 may be a transparent material such as quartz, synthetic quartz, fused silica, magnesium fluoride (MgF₂), calcium fluoride (CaF₂), or any other suitable material that transmits at least 75% of incident light having a wavelength between approximately ten nanometers (10 nm) and approximately 450 nm. In an other embodiments, substrate 16 may be a reflective material such as silicon or any other suitable material that reflects greater than approximately 50% of incident light having a wavelength between approximately 10 nm and 450 nm.

In some embodiments, patterned layer 18 may be a metal material such as chrome, chromium nitride, a metallic oxy-carbo-nitride (e.g., MOCN, where M is selected from the group consisting of chromium, cobalt, iron, zinc, molybdenum, niobium, tantalum, titanium, tungsten, aluminum, magnesium, and silicon), or any other suitable material that absorbs electromagnetic energy with wavelengths in the ultraviolet (UV) range, deep ultraviolet (DUV) range, vacuum ultraviolet (VUV) range and extreme ultraviolet range (EUV). In other embodiments, patterned layer 18 may be a partially transmissive material, such as molybdenum silicide (MoSi), which has a transmissivity of approximately 1% to approximately 30% in the UV, DUV, VUV and EUV ranges.

A frame 20 and a pellicle film 22 may form pellicle assembly 14. Frame 20 may be formed from anodized aluminum, or could alternatively be formed of stainless steel, plastic or other suitable materials that do not degrade or outgas when exposed to electromagnetic energy within a lithography system. Pellicle film 22 may be a thin film membrane formed of a material such as nitrocellulose, cellulose acetate, an amorphous fluoropolymer, such as TEFLON® AF manufactured by E. I. du Pont de Nemours and Company or CYTOP® manufactured by Asahi Glass, or another suitable film that is transparent to wavelengths in the UV, DUV, EUV and/or VUV ranges. Pellicle film 22 may be prepared by a conventional technique such as spin casting, for example.

Pellicle film 22 may protect photomask 12 from contaminants, such as dust particles for example, by ensuring that the contaminants remain a defined distance away from photomask 12. This may be especially important in a lithography system. During a lithography process, photomask assembly 10 may be exposed to electromagnetic energy produced by a radiant energy source within the lithography system. The electromagnetic energy may include light of various wavelengths, such as wavelengths approximately between the I-line and G-line of a Mercury arc lamp, or DUV, VUV or EUV light, for example. In operation, pellicle film 22 may be designed to allow a large percentage of the electromagnetic energy to pass through it. Contaminants collected on pellicle film 22 are likely out of focus at the surface of the wafer being processed and, therefore, the exposed image on the wafer is likely clear. Pellicle film 22 formed in accordance with the teachings of the present invention may be satisfactorily used with all types of electromagnetic energy and is not limited to lightwaves as described in this application.

Photomask 12 may be formed from a photomask blank using any standard lithography process. In a lithography process, a mask pattern file that includes data for patterned layer 18 may be generated from a mask layout file. In one embodiment, the mask layout file may include polygons that represent transistors (or other IC components) and electrical connections for an integrated circuit. The polygons in the mask layout file may further represent different layers of the integrated circuit when it is fabricated on a semiconductor wafer. For example, a transistor may be formed on a semiconductor wafer with a diffusion layer and a polysilicon layer. Therefore, the mask layout file may include one or more polygons drawn on the diffusion layer and one or more polygons drawn on the polysilicon layer. The polygons for each layer may be converted into a mask pattern file that represents one layer of the integrated circuit. Each mask pattern file may be used to generate a photomask for the specific layer. In some embodiments, the mask pattern file may include more than one layer of the integrated circuit such that a photomask may be used to image features from more than one layer onto the surface of a semiconductor wafer.

The desired pattern may be imaged into a resist layer of the photomask blank using a laser, electron beam or X-ray lithography system. In one embodiment, a laser lithography system uses an Argon-Ion laser that emits light having a wavelength of approximately 364 nm. In other embodiments, the laser lithography system uses lasers emitting light at wavelengths from approximately 150 nm to approximately 300 nm. Photomask 12 may be fabricated by developing and etching exposed areas of the resist layer to create a pattern, etching the portions of patterned layer 18 not covered by resist, and removing the undeveloped resist to create patterned layer 18 over substrate 16.

Patterned layer 18 may include one or more components that have geometries that correspond to integrated circuit components to be formed on a semiconductor wafer. During a lithography process, the geometries of such components may be transferred onto a surface of a semiconductor wafer to form the corresponding integrated circuit components. Such integrated circuit components may include, but are not limited to, resistors, transistors, capacitors, interconnects, vias, and metal lines, for example.

In some embodiments, patterned layer 18 may include one or more features 30 (see FIG. 2) that correspond to IC components for which precision and/or accuracy regarding one or more electrical characteristics and/or properties thereof may be important or critical to the proper or desired operation of an IC in which such components are formed. Such IC components may be referred to as critical-performance IC components 32 (see FIG. 2). In some embodiments, critical-performance IC components 32 may include at least two IC components that have one or more matching electrical characteristics. In other embodiments, critical-performance IC components 32 may include two or more IC components that have any suitable matching property that may be important to the proper or desired operation of the IC.

Since electrical characteristics of an IC component may depend at least in part on the physical geometry (including shape and dimensions) of the IC component, the geometry of critical-performance IC components 32 may be important or critical in order to provide the electrical characteristics required for the proper or desired operation of the IC. As discussed above, critical-performance IC components 32 may have one or more electrical characteristics that should match each other. As such, it may be important that the geometries of such IC components either match each other or otherwise provide matching electrical characteristics for the critical-performance IC components 32.

As discussed above, critical-performance IC components 32 may include any IC component(s) for which precision and/or accuracy related to one or more electrical characteristics or properties thereof is important or critical to the proper or desired operation of the IC containing the critical-performance IC components 32. In some embodiments, critical-performance IC components 32 may include a pair (or more) of resistors that are related such that each resistor provides a substantially identical amount of resistance in order to allow for the proper or desired operation of the IC in which they are included. In another embodiments, critical-performance IC components 32 may include a pair (or more) of capacitors that are related such that each capacitor provides a substantially identical amount of capacitance in order to allow for the proper or desired operation of the IC. In another embodiments, critical-performance IC components 32 may include a pair (or more) of inductors that are related such that each inductor provides a substantially identical amount of inductance in order to allow for the proper or desired operation of the IC.

In other embodiments, critical-performance IC components 32 may include one or more IC components having one or more electrical characteristics that substantially match particular predetermined measurements within a particular degree of accuracy. For example, critical-performance IC components 32 may include a resistor that should provide approximately 354 ohms resistance within a tolerance range of approximately +/−2 ohms.

It should be understood that the IC components discussed herein are merely examples, and that critical-performance IC components 32 may include any other type of IC component(s).

FIG. 2 is partial three-dimensional view illustrating a lithography process used in the formation of critical-performance IC components 32 according to an embodiment of the present invention. Patterned layer 18 on photomask 12 may include (among other features not shown) at least one pair of particular features 30a and 30b having geometries that respectively correspond with at least one pair of critical-performance IC components 32a and 32b to be formed on semiconductor wafer 40. Patterned layer 18, including features 30a and 30b, may be formed as described above with regard to FIG. 1, or using any other suitable techniques for forming patterned layer 18 of photomask 12.

Semiconductor wafer 40 may include a plurality of dies, which may also be referred to as chips, that each include one or more integrated circuits containing a variety of IC components. In some embodiments, semiconductor wafer 40 may comprise a thin, circular slice of single-crystal semiconductor material suitable for the manufacturing of semiconductor devices and integrated circuits. Critical-performance IC components 32a and 32b may form a portion of integrated circuit 42 to be formed on semiconductor wafer 40.

As shown in FIG. 2, one or more photolithographic and/or other fabrication processes may be performed, as indicated by arrows 44, to transfer the images formed by patterned layer 18, including features 30a and 30b, onto a first region of semiconductor wafer 40 in order to form integrated circuit 42 (or at least a portion of integrated circuit 42), including critical-performance IC components 32a and 32b. After critical-performance IC components 32a and 32b have been formed, one or more electrical properties of integrated circuit components 32a and/or 32b may be measured, for example, by connecting probes or other measuring devices at particular points on critical-performance IC components 32a and/or 32b or elsewhere in integrated circuit 42. The results of the measurements may be used to determine whether or not one or more of the electrical properties of critical-performance IC components 32a and/or 32b are satisfactory. In one embodiment, the electrical properties of critical-performance IC components 32a and/or 32b may be satisfactory if the measured electrical property matches a predetermined value according to a predetermined level of accuracy or precision.

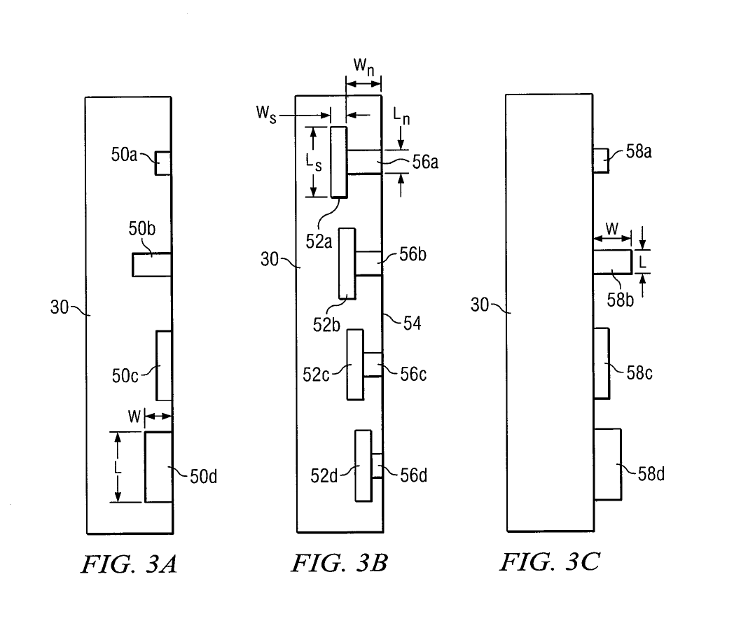

If one or more of the measured electrical properties of critical-performance IC components 32a and/or 32b are not satisfactory, the geometries of one or both of features 30a and 30b in patterned layer 18 may be physically modified. For example, such modification may include any suitable removal or addition of material, as discussed in greater detail below with reference to FIGS. 3A-3C. In some embodiments, the particular physical modification (including the type and/or the amount of the modification) to be performed on features 30a and/or 30b may be determined based on the results of the measurements of the electrical properties.

Once the modifications have been made to one or both of features 30a and 30b, the photolithographic and/or other fabrication processes shown in FIG. 2 may be repeated to transfer the images formed by patterned layer 18, including features 30a and 30b, onto a second region of semiconductor wafer 40, or onto another semiconductor wafer, in order to form integrated circuit 42 (or at least a portion of integrated circuit 42), including critical-performance IC components 32a and 32b. This pair of critical-performance IC components 32a and 32b are preferably distinct from the pair formed in the first region of semiconductor wafer 40.

After the second pair of critical-performance IC components 32a and 32b have been formed, one or more electrical properties of each component may again be measured and determined to be satisfactory or unsatisfactory. If the measured electrical properties are unsatisfactory, the geometries of one or both of features 30a and 30b in patterned layer 18 may again be physically modified. The process of modifying features 30a and/or 30b, forming critical-performance IC components 32a and 32b, and testing critical-performance IC components 32a and/or 32b, may be repeated in an iterative manner until at lease one pair of critical-performance IC components 32a and 32b are formed for which the measured electrical properties are satisfactory.

FIGS. 3A-3C are top views of feature 30 illustrating example ways of modifying the geometry of feature 30 (such as features 30a and/or 30b discussed above, for example) in patterned layer 18 of photomask 12 in accordance with certain embodiments of the present invention.

FIG. 3A illustrates a variety of notches 50, including example notches 50a, 50b, 50c and 50d, that may be formed in feature 30 by removing a portion of the material forming feature 30 in order to reduce the volume or other dimension of feature 30. In one embodiment, one or more notches 50 may be formed in feature 30 using any suitable technique for removing material from feature 30, such as using laser trimming techniques or particular etching processes, for example.

As illustrated with regard to notch 50d, each notch 50 may be defined by a length “L” and a width “W.” In some embodiments, the length L and width W may be determined based on the measurement of electrical properties associated with feature 30. In one embodiment, feature 30 may be used to create a resistor on semiconductor wafer 40 and notches 50 may change the resistance for the corresponding critical-performance components 32 formed on semiconductor wafer 40. For example, forming notch 50a (having a particular length L and width W) in feature 30 may decrease the resistance of the resulting resistor by approximately one percent (1%), forming notch 50b (having a particular length L and width W) in feature 30 may decrease the resistance of the resulting resistor by approximately two percent (2%), forming notch 50c (having a particular length L and width W) in feature 30 may decrease the resistance of the resulting resistor by approximately three percent (3%), and forming notch 50d (having a particular length L and width W) in feature 30 may decrease the resistance of the resulting resistor by approximately four percent (4%). Thus, a notch 50 having particular dimensions L and W may be formed based on the measurements of electrical properties associated with feature 30.

FIG. 3B illustrates a variety of shunts 52, including example shunts 52a, 52b, 52c and 52d, that may be formed in feature 30 by removing a portion of the material forming feature 30. In one embodiment, one or more shunts 52 may be formed in feature 30 using any suitable technique for removing material from feature 30, such as using laser trimming techniques or particular etching processes, for example.

As illustrated with regard to shunt 52a, each shunt 52 may be defined by a length “Lₛ” and a width “Wₛ.” Each shunt 52 may be formed at some distance, indicated at distance “Wₙ,” from a side 54 of feature 30. Shunt 52 may be opened by removing material from feature 30 to form a notch 56 that extends from side 54 of feature 30 to shunt 52. Thus, shunt 52 may be used to provide a predetermined width Wₙ for notch 56. For example, shunt 52a may be opened by forming notch 56a extending from side 54 of feature 30 to shunt 52a. The size of notch 56a may be defined by the width Wₙ and a length Lₙ, as shown in FIG. 3B.

In some embodiments, one or more of the length Lₛ and/or width Wₛ of shunt 52, the distance Wₙ from side 54 of feature 30 to shunt 52 and/or the length Lₙ of the 56 may be determined based on the measurement of one or more electrical properties associated with feature 30. In one embodiment, feature 30 may be used to create a resistor on semiconductor wafer 40 and one or more shunts 52 may change the resistance for the corresponding critical-performance components 32 formed on semiconductor wafer 40. For example, forming and opening shunt 50a (formed at a first particular distance Wₙ from side 54 of feature 30) in feature 30 may decrease the resistance of the resulting resistor by approximately four percent (4%), forming and opening shunt 50b (formed at a second particular distance Wₙ from side 54 of feature 30) in feature 30 may decrease the resistance of the resulting resistor by approximately three percent (3%), forming and opening shunt 50c (formed at a third particular distance Wₙ from side 54 of feature 30) in feature 30 may decrease the resistance of the resulting resistor by approximately two percent (2%), and forming and opening shunt 50d (formed at a fourth particular distance Wₙ from side 54 of feature 30) in feature 30 may decrease the resistance of the resulting resistor by approximately one percent (1%).

In some embodiments, one or more shunts 52 may be pre-formed into feature 30. Based on the measurement of one or more electrical properties associated with feature 30, one or more of preformed shunts 52 may be selected to be opened in order to provide a desired change in the one or more electrical properties. For example, the resistance of a resistor formed using feature 30 having the four shunts 52a-52d, as shown in FIG. 3B, may be measured and, from the measurements, it may be determined that the resistance should be reduced by approximately three percent (3%). Assuming that opening shunt 52b is known to reduce the resistance of a resulting resistor by approximately three percent (3%), shunt 52b may be selected to be opened by forming notch 56b.

FIG. 3C illustrates a variety of extensions 58, including example extensions 58a, 58b, 58c and 58d, that may be formed on feature 30 by adding material adjacent to feature 30 in order to increase the volume or other dimension of feature 30. One or more extensions 58 may be added to feature 30 using any suitable technique for adding material to any feature formed in patterned layer 18 of photomask 12, such as using various deposition techniques, for example. Extensions 58 may or may not be formed from the same material as feature 30.

As illustrated with regard to example extension 58c, each extension 58 may be defined by a length “L” and a width “W.” In some embodiments, the length L and width W may be determined based on the measurement of one or more electrical properties associated with feature 30. In one embodiment, feature 30 may be used to create a resistor on semiconductor wafer 40 and extensions 58 may change the resistance for the corresponding critical-performance components 32 formed on semiconductor wafer 40. For example, forming extension 58a (having a particular length L and width W) in feature 30 may increase the resistance of the resulting resistor by approximately one percent (1%), forming extension 58b (having a particular length L and width W) in feature 30 may increase the resistance of the resulting resistor by approximately two percent (2%), forming extension 58c (having a particular length L and width W) in feature 30 may increase the resistance of the resulting resistor by approximately three percent (3%), and forming extension 58d (having a particular length L and width W) in feature 30 may increase the resistance of the resulting resistor by approximately four percent (4%). Thus, extension 58 having particular dimensions L and W may be formed based on the measurements of electrical properties associated with feature 30.

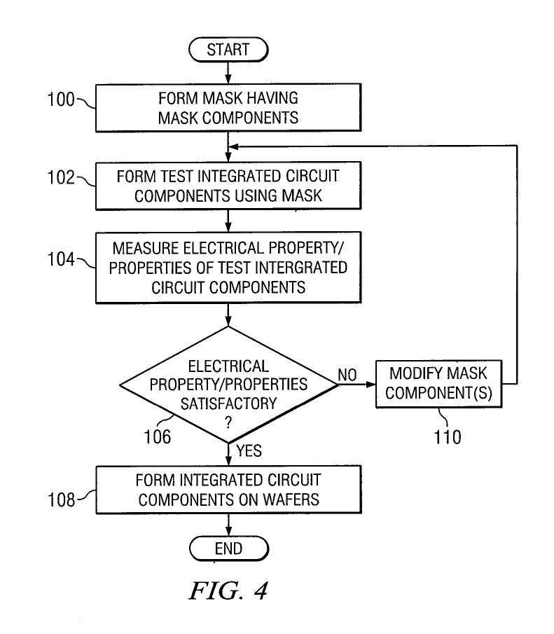

FIG. 4 illustrates a flow chart of an iterative method for forming critical-performance IC components 32 in semiconductor wafer 40 according to an embodiment of the present invention.

At step 100, photomask 12 may be formed having patterned layer 18 including one or more features 30 that correspond to one or more critical-performance IC components 32 to be formed in semiconductor wafer 40. Photomask 12 may be formed using any suitable techniques, including, for example, those discussed herein.

At step 102, one or more photolithographic and/or other fabrication processes may be performed to transfer the images formed by patterned layer 18, including the geometries of features 30, onto wafer 40 in order to form at least a portion of an integrated circuit, including the one or more critical-performance IC components 32.

At step 104, one or more electrical properties of the one or more critical-performance IC components 32 may be measured, such as by connecting probes or other measuring devices at particular points on critical-performance IC components 32 or elsewhere in the integrated circuit, for example. For example, in an instance in which one or more critical-performance integrated circuit components 32 comprise a pair of resistors, the resistance of each resistor may be measured.

At step 106, the measurements collected at step 104 may be used to determine whether or not one or more electrical properties of critical-performance IC components 32 are satisfactory, such as according to some predetermined level of accuracy or precision.

If it is determined that the electrical property/properties of critical-performance IC components 32 are satisfactory, photomask 12 may be used for the fabrication of any number of integrated circuits, including critical-performance IC components 32, on any number of semiconductor wafers, as indicated at step 108.

Alternatively, if it is determined that one or more of the electrical properties of critical-performance IC components 32 are unsatisfactory, it may be determined that the geometries of at least one of features 30 in patterned layer 18 of photomask 12 should be physically modified, as indicated at step 110. Such modification may include any suitable removal or addition of material from at least one of features 30, such as discussed above with reference to FIGS. 3A-3C. In some embodiments, the particular physical modification (include the type and/or the amount of such modification) to be performed may be determined based on the results of the measurements of the one or more electrical properties.

Once the modifications have been made to photomask 12 at step 110, the method may return to step 102 to form a new set of critical-performance IC components 32 on another semiconductor wafer (or on a different region of the same semiconductor wafer). The electrical properties of this new set of critical-performance IC components 32 may then be measured at step 104, determined satisfactory or unsatisfactory at step 106, and again modified at step 108 if determined to be still unsatisfactory. This iterative process may continue until a set of critical-performance IC components 32 is formed for which the measured electrical properties are determined satisfactory at step 106. Thus, features 30 in patterned layer 18 of photomask 12 may be modified any number of times until they are operable to produce critical-performance IC components 32 having satisfactory electrical characteristics.

By modifying pattern layer 18 of photomask 12 according to the iterative process discussed above, the resulting photomask 12 may be used to form critical-performance IC components 32 having satisfactory electrical characteristics on multiple semiconductor wafers. Thus, the amount of modification (such as trimming or laser ablation, for example) to critical-performance IC components 32 on the fabricated wafers may be reduced or eliminated as compared with previous techniques for producing critical-performance integrated circuit components. As a result, the efficiency of fabrication process may be increased.

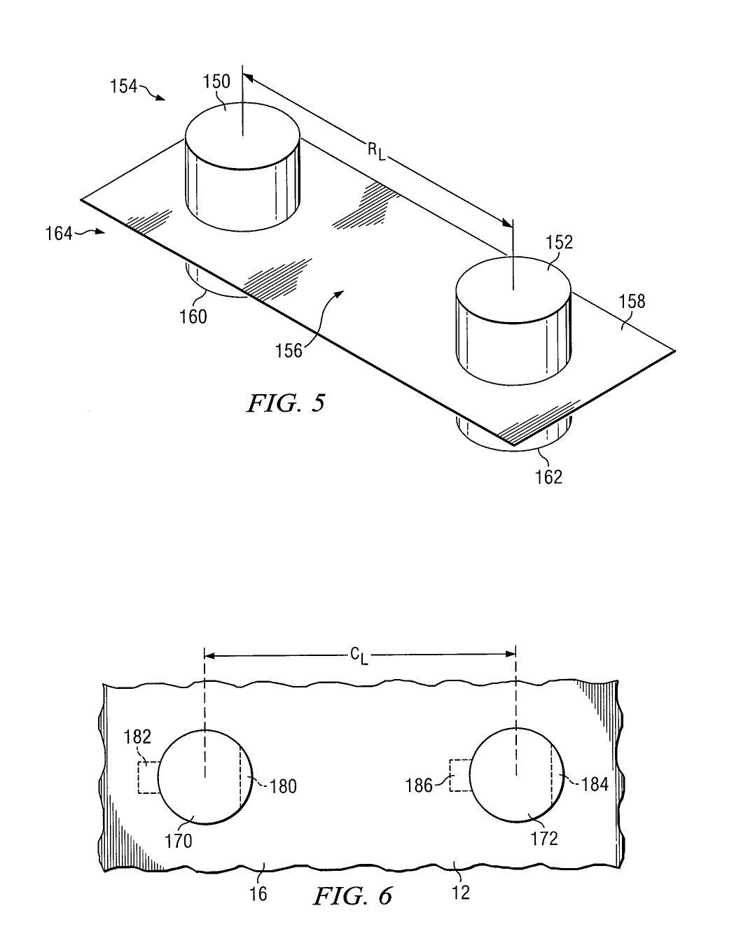

FIG. 5 is a three-dimensional view illustrating a portion of an integrated circuit formed in a semiconductor wafer in accordance with an embodiment of the present invention. In particular, the portion of an integrated circuit shown in FIG. 5 may include a first pair of interconnects, or vias, 150 and 152 formed in a first layer 154, a resistor 156 formed in a second layer 158, and a second pair of interconnects, or vias, 160 and 162 formed in a third layer 164. Each of the interconnects 150, 152, 160 and 162 may be physically coupled to resistor 156. This formation of components may provide a variety of potential circuits including resistor 156 and a pair of interconnects, such pair of interconnects potentially comprising (1) interconnects 150 and 152, (2) interconnects 150 and 162, (3) interconnects 160 and 162, and/or (4) interconnects 160 and 152, for example. For illustrative purposes only, the following discussion focuses on the potential circuit including resistor 156 and interconnects 150 and 152.

As is well known in the art, the resistance of a resistor in an integrated circuit depends in part on the effective distance between the contacts coupled to the resistor. Thus, in this example, the resistance of resistor 156 depends in part on the effective distance between interconnects 150 and 152, indicated in FIG. 5 as length R_{L}. The effective distance R_{L} between interconnects 150 and 152 may be defined based on the distance between an effective contact point between interconnect 150 and resistor 156 and an effective contact point between interconnect 152 and resistor 156. By changing the effective distance R_{L} between interconnects 150 and 152, the resistance of resistor 156 may be changed.

As discussed below with reference to FIG. 6, a photomask used for forming interconnects 150 and 152 may be tested and modified using a iterative process to form a desired photomask that produces interconnects 150 and 152 separated by an effective distance R_{L} that produces a desired resistance from resistor 156. The photomask may then be used to form interconnects 150 and 152 on any suitable number of wafers, which may thus reduce or eliminate the amount of modification (such as trimming or laser ablation, for example) to interconnects 150 and 152 on the fabricated wafers, which may thereby reduce cycle time, increase throughput, and/or reduce costs.

FIG. 6 is a top view of a portion of photomask 12 having patterned layer 18 including a pair of mask features 170 and 172 used to form interconnects 150 and 152 (see FIG. 5) in accordance with an embodiment of the present invention. One or more photolithographic and/or other fabrication processes may be performed to transfer the images formed by patterned layer 18, including the geometries of mask features 170 and 172, onto a semiconductor wafer in order to form interconnects 150 and 152. It should be understood that one or more other photomasks 12 may be used in one or more other photolithographic and/or other fabrication processes to form resistor 156 and interconnects 160 and 162, which may be formed prior to the formation of interconnects 150 and 152.

At some point after resistor 156 and interconnects 150 and 152 have been formed, the resistance (and/or one or more other electrical properties) of resistor 156 may be measured, such as by connecting probes or other measuring devices at interconnects 150 and 152 or elsewhere in the circuit. Based on the results of such measurements, it may be determined whether or not the measured resistance of resistor 156 is satisfactory, such as according to some predetermined level of accuracy or precision.

If the measured resistance of resistor 156 is satisfactory, photomask 12 may be used for the fabrication of interconnects 150 and 152 in any number of integrated circuits on any number of semiconductor wafers. Alternatively, if the measured resistance of resistor 156 is unsatisfactory, it may be determined that the effective distance R_{L} between interconnects 150 and 152 should be changed in order to change the resistance of resistor 156. In order to change the effective distance R_{L} between interconnects 150 and 152 formed on subsequent wafers, the geometries of at least one of mask features 170 and 172 may be modified to adjust the effective distance between mask features 170 and 172, indicated in FIG. 6 as length C_{L}.

Such modification of the geometries of mask features 170 and/or 172 may include any suitable removal and/or addition of material to mask features 170 and/or 172. For example, in some embodiments, notches may be formed in, or extensions maybe formed adjacent, mask features 170 and/or 172, such as described above with reference to FIGS. 3A-3C, for example. Example modifications are shown in FIG. 6. For example, regarding mask feature 170, a portion of mask feature 170 facing mask feature 172, indicated as portion 180, may be removed in order to increase the effective distance C_{L} between mask features 170 and 172. Alternatively, an extension may be formed adjacent the side of mask feature 170 furthest from mask feature 172, indicated as extension 182, in order to increase the effective distance C_{L} between mask features 170 and 172. As another example, regarding mask feature 172, a portion of mask feature 172 furthest from mask feature 170, indicated as portion 184, may be removed in order to decrease the effective distance C_{L} between mask features 170 and 172. Alternatively, an extension may be formed adjacent the side of mask feature 170 facing mask feature 170, indicated as extension 186, in order to decrease the effective distance C_{L} between mask features 170 and 172. Any suitable combination of such removals and/or additions of material may be employed to modify the effective distance C_{L} between mask features 170 and 172 as desired. In some embodiments, the particular physical modification (include the type and/or the amount of such modification) to be performed on one or both of mask features 170 and 172 may be determined based on the results of the measured resistance of resistor 156.

Once the modifications have been made to mask features 170 and/or 172 as discussed above, the one or more photolithographic and/or other fabrication processes may be again performed to transfer the images formed by patterned layer 18, including the modified geometries of mask features 170 and 172, onto another semiconductor wafer (or onto a different region of the same wafer) in order to form a new set of interconnects 150 and 152 on the wafer. Again, one or more other photomasks 12 may be used in one or more other photolithographic and/or other fabrication processes to form resistor 156 and interconnects 160 and 162, which may be formed prior to the formation of interconnects 150 and 152.

After the resistor 156 and second pair of interconnects 160 and 162 have been formed on the new wafer (or new portion of the same wafer), the resistance of resistor 156 may again be measured and determined to be satisfactory or unsatisfactory. If the resistance of resistor 156 is still unsatisfactory, the geometries of one or both of mask features 170 and 172 of photomask 12 may again be physically modified in order to change the effective distance C_{L} between mask features 170 and 172, thus changing the effective distance R_{L} between interconnects 160 and 162 and changing the resistance of resistor 156. This process of modifying mask features 170 and/or 172, forming test resistors 156 and interconnects 160 and 162, and testing test resistors 156, may be repeated in an iterative manner until a resistor is formed having a satisfactory resistance.

Although the present invention has been described with respect to a specific preferred embodiment thereof, various changes and modifications may be suggested to one skilled in the art and it is intended that the present invention encompass such changes and modifications fall within the scope of the appended claims.

What is claimed is:

1. A method of forming integrated circuit components, comprising:
providing a photomask including a first mask feature having a first mask feature geometry corresponding to a first type of integrated circuit (IC) component;
performing a first lithography process to transfer the first mask feature geometry to a first semiconductor wafer region to form a first IC component in the first semiconductor wafer region;
measuring at least one electrical characteristic of the first IC component; and
based at least on the results of measuring the at least one electrical characteristic of the first IC component, physically modifying the first mask feature geometry.

2. The method of claim 1, further comprising:
performing a second lithography process to transfer the modified first mask feature geometry of the first mask feature to a second semiconductor wafer region to form a second IC component in the second semiconductor wafer region;
measuring the at least one electrical characteristic of the second IC component;
if the results of measuring the at least one electrical characteristic of the second IC component are unsatisfactory, physically modifying the modified first mask feature geometry; and
if the results of measuring the at least one electrical characteristic of the second IC component are satisfactory, performing at least one additional lithography process to transfer the modified mask feature geometry to at least one additional semiconductor wafer region to form at least one IC component in the one or more semiconductor wafer regions.

3. (canceled)

4. The method of claim 1, wherein:
the first IC component comprises a resistor or a capacitor; and
measuring at least one electrical characteristic of the first IC component comprises measuring resistance of the resistor or measuring the capacitance of the capacitor.

5. (canceled)

6. The method of claim 1, wherein physically modifying the first mask feature geometry comprises physically removing a portion of the first mask feature.

7. The method of claim 6, wherein physically removing the portion of the first mask feature comprises forming a notch in the first mask feature.

8. The method of claim 6, wherein physically removing the portion of the first mask feature comprises:
forming a shunt in the first mask feature; and
opening the shunt by forming a notch extending from a side of the first mask feature to the shunt.

9. The method of claim 1, wherein physically modifying the first mask feature geometry comprises adding an extension to the first mask feature by depositing a material to form the extension extending from at least one side of the first mask feature.

10. (canceled)

11. A method of forming integrated circuit components, comprising:
providing a photomask including a first mask feature having a first mask feature geometry corresponding to a first type of integrated circuit (IC) component and a second mask feature having a second mask feature geometry corresponding to a second type of IC component;
performing a first lithography process to transfer the first and second mask feature geometries to a first semiconductor wafer region to form a first IC component and a second IC component in the first semiconductor wafer region;
measuring at least one electrical characteristic of the first IC component in the first semiconductor wafer region;
measuring at least one electrical characteristic of the second IC component in the first semiconductor wafer region;
comparing the at least one measured electrical characteristic of the first IC component with the at least one measured electrical characteristic of the second IC component; and
based on the comparison of the measured electrical characteristics, determining whether to physically modify at least one of the first mask feature geometry and the second mask feature geometry.

12. The method of claim 11, further comprising physically modifying at least one of the first mask feature geometry and the second mask feature geometry based on the comparison of the measured electrical characteristics.

13. The method of claim 12, further comprising:
performing a second lithography process to transfer the first mask feature geometry and the second mask feature geometry to a second semiconductor wafer region to form a third IC component and a fourth IC component in the second semiconductor wafer region, the photomask used in the second lithography process including the modification to at least one of the first mask feature geometry and the second mask feature geometry;
measuring at least one electrical characteristic of at least one of the third IC component and fourth integrated IC in the second semiconductor wafer region;
if the results of measuring the at least one electrical characteristic are unsatisfactory, physically modifying at least one of the first mask feature geometry and the second mask feature geometry; and
if the results of measuring the at least one electrical characteristic are satisfactory, performing at least one additional lithography process to transfer the first mask feature geometry and the second mask feature geometry to at least one additional semiconductor wafer region to form additional IC components in the at least one additional semiconductor wafer region.

14. (canceled)

15. The method of claim 11, wherein:
the first IC component and the second IC component comprise resistors or capacitors;
measuring at least one electrical characteristic of the first IC component comprises measuring resistance or capacitance of the first IC component; and
measuring at least one electrical characteristic of the second IC component comprises measuring resistance or capacitance of the second IC component.

16. (canceled)

17. The method of claim 12, wherein physically modifying at least one of the first mask feature geometry and the second mask feature geometry comprises physically removing a portion of the first mask feature.

18. The method of claim 17, wherein physically removing a portion of the first mask feature comprises forming a notch in the first mask feature.

19. The method of claim 17, wherein physically removing a portion of the first mask feature comprises:
forming a shunt in the first mask feature; and
opening the shunt by forming a notch extending from a side of the first mask feature to the shunt.

20. The method of claim 12, wherein physically modifying at least one of the first mask feature geometry and the second mask feature geometry comprises adding an extension to the first mask feature by depositing a material to form the extension extending from at least one side of the first mask feature.

21-22. (canceled)

23. A method of forming integrated circuit components, comprising:
providing a first photomask including a first mask feature having a first mask feature geometry corresponding to a first type of integrated circuit (IC) component;
providing a second photomask including one or more second mask features each having a second mask feature geometry corresponding to a second type of IC component;
performing a first lithography process using the first photomask to transfer the first mask feature geometry to a first semiconductor wafer region to form the first IC component in the first semiconductor wafer region;
performing a second lithography process using the second photomask to transfer the second mask feature geometry to the first semiconductor wafer region to form one or more second IC components in the first semiconductor wafer region, each of the one or more second IC components being coupled to the first IC component;
measuring at least one electrical characteristic of the first IC component; and
based at least on the results of measuring the at least one electrical characteristic of the first IC component, physically modifying the second mask feature geometry of at least one of the one or more second mask features.

24. The method of claim 23, wherein:
performing the first lithography process comprises forming the first IC component in a first layer in the first semiconductor wafer region; and
performing the second lithography process comprises forming the one or more second IC components in a second layer in the first semiconductor wafer region, the second layer being adjacent to the first layer.

25. The method of claim 23, wherein:
the one or more second mask features comprise a pair of second mask features each having a second mask feature geometry corresponding to a second type of IC component;
performing the second lithography process comprises performing the second lithography process using the first photomask to transfer the second mask feature geometry of each of the pair of second mask features to the first semiconductor wafer region to form a pair of second IC components in the first semiconductor wafer region, each of the pair of second IC components being coupled to the first IC component at an effective contact point; and
physically modifying the second mask feature geometry comprises modifying a distance between the effective contact points between the pair of second mask features and the first IC component.

26. The method of claim 25, wherein:
the first IC component comprises a resistor;
the pair of second IC components comprises a pair of interconnects coupled to the resistor such that the resistance of the resistor depends at least in part on the distance between the effective contact points between the pair of interconnects and the resistor; and
measuring at least one electrical characteristic of the first IC component comprises measuring the resistance of the resistor.

27. The method of claim 25, wherein modifying the distance between the effective contact points between the pair of second mask features and the first IC component comprises removing a portion of at least one of the pair of second mask features to increase or decrease the distance between the effective contact points between the pair of second mask features and the first IC component.

28. The method of claim 25, wherein modifying the distance between the effective contact points between the pair of second mask features and the first IC component comprises adding an extension to at least one of the pair of second mask features to increase or decrease the distance between the effective contact points between the pair of second mask features and the first IC component.

29. The method of claim 23, further comprising:
physically modifying the second mask features geometry;
performing a third lithography process using the first photomask to transfer the first mask feature geometry to a second semiconductor wafer region to form the first IC component in the second semiconductor wafer region;
performing a fourth lithography process using the second photomask to transfer the second mask feature geometry to the first semiconductor wafer region to form one or more second IC components in the second semiconductor wafer region, each of the one or more second IC components being coupled to the first IC component, the second photomask used in the fourth lithography process including the modification to the second mask feature geometry;
measuring at least one electrical characteristic of the first IC component in the second semiconductor wafer region;
if the results of measuring the at least one electrical characteristic of the first IC component are unsatisfactory, physically modifying the second mask feature geometry; and
if the results of measuring the at least one electrical characteristic of the first IC component in the second semiconductor wafer region are satisfactory, performing one or more additional lithography processes to transfer the second mask feature geometry to one or more additional semiconductor wafer regions to form one or more second IC in the one or more semiconductor wafer regions.

30. (canceled)

31. An integrated circuit device comprising a particular integrated circuit component formed in a particular semiconductor wafer region, the particular integrated circuit component formed at least by:
providing a photomask including a first mask feature having a first mask feature geometry corresponding to a first type of integrated circuit (IC) component;
performing a first lithography process to transfer the first mask feature geometry to a test semiconductor wafer region to form a test IC component in the test semiconductor wafer region;
measuring at least one electrical characteristic of the test IC component; and
based at least on the results of measuring the at least one electrical characteristic of the test IC component, physically modifying the first mask feature; and
performing a second lithography process to transfer the modified first mask feature geometry to the particular semiconductor wafer region to form the particular IC component in the second semiconductor wafer region.

32. The integrated circuit device of claim 31, wherein:
the test IC component comprises a resistor or a capacitor; and
measuring at least one electrical characteristic of the test IC component comprises measuring resistance of the resistor or the capacitance of the capacitor.

33-36. (canceled)
